(19) United States
(12) Patent Application Publication
(10) Pub. No.: US 2025/0012669 A1
(43) Pub. Date: Jan. 9, 2025

(54) METHOD FOR DETECTING AN OPEN LOAD FAULT

(71) Applicant: Robert Bosch GmbH, Stuttgart (DE)

(72) Inventors: Andreas Schwaerzle, Stuttgart (DE); Florian Dencker, Oehringen (DE); Siyun Chu, Ludwigsburg (DE); Wolfram Schreiber, Schwaikheim (DE)

(21) Appl. No.: 18/710,009

(22) PCT Filed: Nov. 23, 2022
(86) PCT No.: PCT/EP2022/082899

§ 371 Date: May 14, 2024

(30) Foreign Application Priority Data
Nov. 24, 2021 (DE) 10 2021 213 204.9

(51) Int. Cl. G01M 15/10; G01R 27/02

(52) U.S. Cl. CPC G01M 15/104; G01R 27/02

(57) ABSTRACT

A method for detecting an open load fault of a wideband lambda sensor of a motor vehicle. The wideband lambda sensor includes at least one heater. The method includes: a) enabling a fault check, wherein a temperature model is used to check if the wideband lambda sensor (112) is sufficiently heated; b) carrying out the fault check; if no fault is detected according to the fault check, the following step is carried out: b1) concluding the method with a result of OK; if a fault is detected according to the fault check, the following step is carried out: b2) concluding the method with a result of not OK; before step b) is carried out, the necessity of overheating protection is checked, and if the overheating protection is necessary, a heater voltage of the heater is reduced simultaneously with step a) or before step a) is carried out.

### BACKGROUND INFORMATION

Lambda sensors are used in internal combustion engines for compliance with applicable emissions regulations. Lambda sensors are generally described in, for example: Konrad Reif (pub.): Sensoren im Kraftfahrzeug, 1st edition 2010, pages 160-165. Wideband lambda sensors in particular are used in both gasoline and diesel systems. A measured lambda signal can be used by many functions of a control device and can, for example, be used to improve exhaust gas aftertreatment and to monitor the efficiency of a three-way catalytic converter.

The wideband lambda sensor can be used to determine an oxygen concentration in the exhaust gas over a wide range. A measured lambda can define a ratio of a current air-fuel ratio to a stoichiometric air-fuel ratio. The wideband lambda sensor typically delivers a clearly continuous lambda signal in the range from 0.7 to air. The wideband lambda sensor usually has individual ceramic foils that are layered on top of each other. Since the wideband lambda sensor, in principle, only functions when the sensor ceramic has a sufficiently high working temperature, the ceramic is heated electrically. In order to reach the required ceramic temperature as quickly as possible, a heating element is usually integrated between the ceramic layers. In principle, the wideband lambda sensor is only ready for operation when it has reached a defined ceramic temperature, and tolerances of the wideband lambda sensor specified in a technical customer document apply here. An evaluation of the signals provided by the wideband lambda sensor is generally carried out via a specific evaluation module (ASIC) integrated in the control device. Digital components or digital/analog components are typically used here. An electrical pumping current that is proportional to the oxygen concentration in the exhaust gas can flow between an external pumping electrode of the wideband lambda sensor and the evaluation module. In the case of a lean exhaust mixture, the pumping current is in principle positive and in the case of a rich mixture, it is negative. In an ideal state, i.e., at a ratio of lambda=1, the pumping current is in principle zero. The evaluation module usually evaluates the measured current and provides an output voltage for further processing in the control device.

The wideband lambda sensor can in particular comprise a wiring harness, connectors in connection with the evaluation module, including a separate output stage for the sensor heating and a software component driver for operating the wideband lambda sensor and for providing a physical lambda signal for the lambda-based functions of the control device. In order to achieve optimum use, the lambda-based functions of the control device in principle require a very high-quality lambda signal over their entire service life. Since the wideband lambda sensor in principle has a significant influence on exhaust emissions, various diagnostic functions are in principle required, which can include in particular a diagnosis of the cable connections, a diagnosis of the output stages, a diagnosis of the heating output of the sensor heater, a diagnosis of the signal availability and time to closed loop and/or a diagnosis of symmetrical and asymmetrical dynamic faults (filter and delay).

Since a diagnosis of the cable connections can only be made by evaluating the internal resistance conditions of the wideband lambda sensor, the sensor ceramic must have exceeded a defined operating temperature for the open load diagnosis (detection of a cable break).

The heating performance diagnosis can also be based on a temperature derived from the resistance of the sensor ceramic. It is therefore in principle not possible to clearly distinguish whether the resistance of the sensor ceramic is outside the measurable range (possible heater fault) or whether there is an open line. Currently, open load diagnosis can be enabled by a sensor temperature model. With this model, it must be ensured that a weak heater or WPA heater (Worst Performance Acceptable) is already sufficiently heated to carry out a robust diagnosis in the field, while overheating of a stronger heater (BP or Best Performing heater) must generally be excluded for reasons of component protection.

### SUMMARY

A method for detecting an open load fault of a wideband lambda sensor, a system comprising at least one wideband lambda sensor and at least one controller, a computer program and a data carrier are provided according to the present invention, which at least largely avoid the disadvantages of conventional devices and methods described above. In particular, a conflict of objectives between cable break detection of the signal line and a heating power fault is to be resolved. Furthermore, it should be possible to ensure protection against overheating while taking into account a high manufacturing tolerance.

In a first aspect of the present invention, a method is provided for detecting an open load fault of a wideband lambda sensor, which is designed to sense at least one property of an exhaust gas in an exhaust gas space of a motor vehicle. The wideband lambda sensor includes at least one heater. The term “wideband lambda sensor” in principle refers to any device which is designed to provide current measurement data for a gasoline or diesel engine in the exhaust gas space to an engine control device, in particular in order to reduce the pollutant content of the exhaust gas. In particular, the wideband lambda sensor can be designed to determine a residual oxygen content in the exhaust gas. This allows the engine control device to optimize the fuel mixture accordingly. In principle, the method for detecting an open load fault is also suitable for jump sensors and NO.: sensors. In this case, the temperature signal can be ascertained by evaluating a ceramic resistance.

The term “heater” in principle refers to any element that is designed to bring the wideband lambda sensor to a required working temperature shortly after a cold start. This makes it possible in principle to ensure emission-optimized operation even during a warm-up phase of the engine. The term “cold start” refers to starting a motor vehicle that has not been previously warmed up. In particular, when starting, all components of the motor vehicle can have an identical temperature level. In particular, all temperature sensors of the motor vehicle can have an identical temperature level. In particular, the wideband lambda sensor can have a temperature of less than 50° C. in the case of a cold start.

The method according to an example embodiment of the present invention is an on-board diagnosis (OBD) for monitoring compliance with emission limits, in particular legally defined emission limits. If a fault in the system has the result that exhaust emission limits can no longer be complied with, a fault can be detected and entered into the fault memory of a control device. As stated above, the method according to the present invention is a method for detecting an open load fault. The method can therefore also be called open load diagnosis. The open load diagnosis can correspond to a detection of a cable break.

The method according to an example embodiment of the present invention comprises the steps listed below. The method may include further steps which are not specified. In particular, the steps can be carried out one after the other and at least partially repeatedly.

The method comprises the following steps:
a) enabling a fault check, wherein a temperature model is used to check if the wideband lambda sensor (112) is sufficiently heated;
b) carrying out the fault check;
wherein if no fault is detected according to the fault check, the following step is carried out:
   b1) concluding the method with a result of OK;
wherein if a fault is detected according to the fault check, the following step is carried out:
   b2) concluding the method with a result of not OK;
wherein before step b) is carried out, the necessity of overheating protection is checked, and if the overheating protection is necessary, a heater voltage of the heater is reduced simultaneously with step a) or before step a) is carried out.

According to an example embodiment of the present invention, the method may in particular be a computer-implemented method. The term “computer-implemented” may in particular refer to a process which is implemented entirely or partially using data processing means, in particular using at least one processor.

The term “enabling” in principle refers to a process in which an implementation of a method step is approved when certain conditions are present. After the enabling has taken place, the method step can be carried out. If no enabling takes place, the method step is not carried out. If the fault check is enabled in step a), it is possible in particular to check whether an operating temperature of a wideband lambda sensor ascertained by the temperature model exceeds a defined limit value.

The term “overheating protection” in principle refers to a safety function of the wideband lambda sensor. The higher the heater voltage of the heater, the higher the heat generation of a coil of the heater, and thus also of the wideband lambda sensor, can be. If a temperature of the heater or of the wideband lambda sensor exceeds a defined limit value, overheating protection may be necessary.

According to an example embodiment of the present invention, in the fault check in step b), a measured internal resistance can be compared with a diagnostic threshold. In case of a two-cell sensor, in particular a wideband two-cell sensor, the internal resistance between the following signal lines can be taken into account: OPE (outer pump electrode) and IPN (inner pump and Nernst electrode) as well as between RE (reference electrode) and IPN. In case of a single cell sensor, in particular a wideband single cell sensor, the internal resistance between the following signal lines can be taken into account: between OPE and IPN. A temporal signal curve can be taken into account in that a plurality of consecutive individual measurements are carried out for a robust fault detection.

As stated above, if no fault is detected after the fault check, the method is completed with the OK result. The term “OK result” can in particular refer to a presence of an OK system. The OK system can in particular be a fault-free system for which there is in particular no definition of a state such as new, run-in, or aged.

As stated above, if a fault is detected after the fault check, the method is terminated with the result not OK. The term “not OK result” can in particular refer to the presence of a not OK system. The not OK system can in particular be a faulty system for which there is in particular a definition of a state such as new, run-in, or aged.

As stated above, in step a) the temperature model is used to check whether the wideband lambda sensor is sufficiently heated

The temperature of the wideband lambda sensor can in principle be ascertained only if the wideband lambda sensor is brought by the heater, in particular a sensor heater, into a required temperature operating window, i.e., from approx. 550° C. at a sensor ceramic of the wideband lambda sensor. The temperature operating window of approx. 550° C. corresponds to the current state of the art, but may also be lower if necessary. Since there is basically no way of ascertaining the temperature of the wideband lambda sensor during the heating process of the wideband lambda sensor, the temperature model can be configured to ascertain an energy and/or a quantity of heat which is introduced into the wideband lambda sensor by the heater. The temperature model can take a current battery voltage of the vehicle and/or a duty cycle of a heater output stage into account. Based on the values, the temperature reached by the wideband lambda sensor can be ascertained.

According to an example embodiment of the present invention, the temperature model can be based on different state variables. The state variables can in particular be a temperature and/or an energy. For an energy balance, in particular in an energy or temperature form, an electrical energy of the heater and/or at least one other form of energy transfer can be taken into account, if necessary also all taken together for all forms of transfer. Possible forms of transfer are thermal radiation, convection, and/or conduction. Depending on the model, these forms of transfer can lead to cooling (environment is colder) or heating (environment is hotter) of the wideband lambda sensor. In addition, there can be a cooling model for an initialization after a control device start.

The temperature model can be selected from the group consisting of: a WPA model, a BP model, and a WPA/BP model.

The BP model (Best Performance Model) is in principle a fault-free system. In particular, the fault-free system can have a lowest specified resistance of the heater according to a manufacturing tolerance.

The WPA model (Worst Case Acceptable Model) can in particular be a fault-free system which has aged, i.e., it is only just able to comply with the exhaust emission limits. This can in particular be the case for a motor vehicle at the end of its service life. In principle, all the necessary verification measurements for approval by an authority are carried out on an aged system in a fault system.

Differences between the BP model and the WPA model can be found in an initialization after a restart. The WPA model can cool down more quickly due to its robustness. The BP model allows for slower cooling due to safety in case of overheating. In addition, differences of more than 50% can be common for a heater resistance in a cold state and a hot state.

In particular, the WPA/BP model can be a combination of the BP model and the WPA model.

In a first variant of the present invention, the temperature model can have in particular two functions. The temperature model can be configured to ascertain a minimum necessary energy threshold for enabling the method according to the present invention. Furthermore, the temperature model can be configured to protect the wideband lambda sensor from overheating.

In the first variant, the temperature model can be a WPA/BP model. The WPA/BP model can be used to check whether the wideband lambda sensor is sufficiently heated. Furthermore, the necessity of overheating protection can be checked using the WPA/BP model.

In the first variant, the reduction of the heater voltage of the heater can be carried out simultaneously with step a). In particular, the heater voltage can be reduced at the same time as the fault check is enabled. Depending on a selection of a reduced effective heater voltage, a debounce time can be extended.

In a second variant of the present invention, the temperature model, in particular the temperature model in step a), can be a WPA model. The necessity for overheating protection can be checked using another temperature model. In particular, the further temperature model can be a BP model. By separately modeling the WPA model for enabling fault checking and a BP model for overheating protection, an additional degree of freedom can be provided, which makes it possible to take into account a wider range of heater resistances. This becomes particularly relevant when a WPA heater is not yet warm enough to perform a robust diagnosis, while the BP heater is already threatening to overheat.

In a further aspect of the present invention, a system comprising at least one wideband lambda sensor and at least one controller is provided. The controller includes at least one processor. The controller is designed to carry out the method steps according to the method of the present invention as described above or as described below.

In a further aspect of the present invention, a computer program is proposed which is configured to carry out the method of the present invention as described above or as described below when executed on a computer or computer network.

In a further aspect of the present invention, a computer program having program code means is proposed. The computer program is designed to carry out the method of the present invention as described above or as described below when the program is executed on a computer or computer network.

In a further aspect of the present invention, a data carrier is proposed, on which a data structure is stored. The data structure is designed to execute the method of the present invention as described above or as described below after being loaded into a working and/or main memory of a computer or computer network.

In a further aspect of the present invention, a computer program product is proposed with program code means stored on a machine-readable carrier in order to carry out the method of the present invention as described above or as described below when the program is executed on a computer or computer network.

A computer program product is understood to be the program as a commercially available product. In principle, it can be in any form, for example on paper or on a computer-readable data carrier, and can in particular be distributed via a data transmission network. In particular, the program code means can be stored on a computer-readable data carrier and/or a computer-readable storage medium. The terms “computer-readable data carrier” and “computer-readable storage medium” as used herein may refer in particular to non-transitory data storage devices, such as a hardware data storage medium on which computer-executable instructions are stored. The computer-readable data carrier or the computer-readable storage medium can in particular be or comprise a storage medium such as a random-access memory (RAM) and/or a read-only memory (ROM).

In a further aspect of the present invention, a modulated data signal is provided, wherein the modulated data signal comprises instructions executable by a computer system or computer network for carrying out a method of the present invention as described above or as described below.

The method and the devices according to the present invention have numerous advantages over conventional methods and devices. In particular, the conflict of objectives between cable break detection and heating power faults can be resolved by clearly distinguishing between cable faults on the sensor side and faults that reduce the heating power on the heater side of the sensor.

The requirements for a sensor temperature model regarding robust diagnosis and ensuring component protection can be realized by two different models. Modern lambda sensors generally have very strong and therefore low-resistance heaters. However, due to the manufacturing process, which may include a screen printing process and/or a sintering process, there is generally large variations in the heater resistance. Separating the requirements into two different temperature models can make it possible to intervene in the heater control in the event of an impending overheating of the sensor element, in order to give a weaker, higher-resistance heater enough time to sufficiently heat up the sensor element for an open load diagnosis. In addition, an improvement in diagnostic robustness can also be achieved with a temperature model in which the heater control is adjusted with diagnosis enabling.

In a fault-free system, the open load diagnosis is generally enabled via a defined temperature threshold. Since, in principle, no temperature signal is available in the faulty system, the diagnosis is always enabled using a sensor temperature model. In the related art, open load diagnosis can be enabled using a WPA/BP model, which in principle has to provide robust diagnosis and overheating protection at the same time. The debounce time in this case must be long enough to ensure the diagnosis result, but must be as short as possible for reasons of overheating protection.

With the proposed method of the present invention, the permissible debounce time can be increased by simultaneously reducing the heater voltage and enabling the open load diagnosis. Depending on the selection of the reduced effective heater voltage, the debounce time can be extended.

Furthermore, the proposed method of the present invention allows the requirements for robust diagnosis and overheating protection to be divided between two heater models. By separately modeling the WPA model for enabling the open load diagnosis and a BP model for overheating protection, an additional degree of freedom can be provided which makes it possible to take into account a wider range of heater resistances. This becomes particularly relevant when a WPA heater is not yet warm enough to perform a robust diagnosis, while the BP heater is already threatening to overheat.

Both variants make it possible to increase the effective energy input for heating the sensor without the risk of damaging the sensor.

### BRIEF DESCRIPTION OF THE DRAWINGS

Further optional details and features of the present invention result from the following description of preferred exemplary embodiments shown schematically in the figures.

FIG. 1 shows an overall overview of a system comprising a control device, a lambda sensor, and a cable and sensor connector, with which the method according to the present invention can be carried out.

FIG. 2 is a software schematic diagram, according to an example embodiment of the present invention.

FIGS. 3A and 3B are further flow charts of the method according to an example embodiment of the present invention.

FIGS. 4A to 4C show temperature curves for a lambda sensor ceramic.

FIG. 5 shows temperature curves and sensor voltage signals for a lambda sensor ceramic.

### DETAILED DESCRIPTION OF EXAMPLE EMBODIMENTS

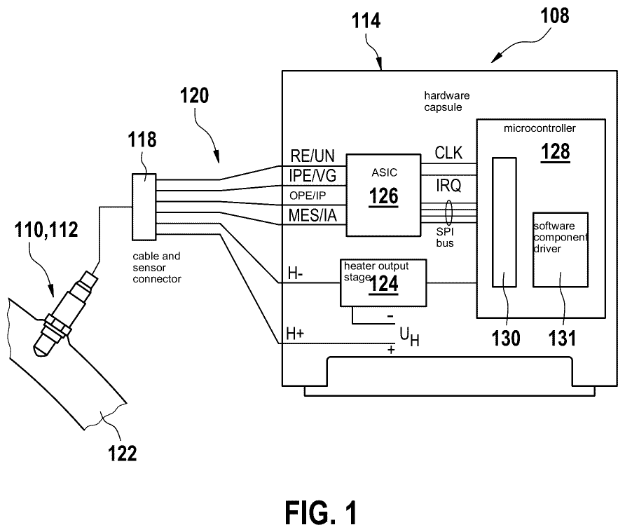

FIG. 1 shows an overall overview of a system 108 comprising a lambda sensor 110, in particular a wideband lambda sensor 112, a control device 114 and a cable and sensor connector 118, with which the method according to the present invention can be carried out.

The lambda sensor 110 can be connected to the control device 114 via the cable and sensor connector 118 and a wiring harness 120. The lambda sensor 110 can be screwed into an exhaust pipe 122. The control device 114 can have a heater output stage 124 for a sensor heater, an ASIC 126, in particular an ASIC CJ135, and a microcontroller 128. The microcontroller 128 can comprise a hardware capsule 130 and a software component driver 131 for the lambda sensor 110.

The ASIC 126 can in particular be a hardware component for controlling and converting sensor signals which are provided to the microcontroller 128 for the software component driver 131.

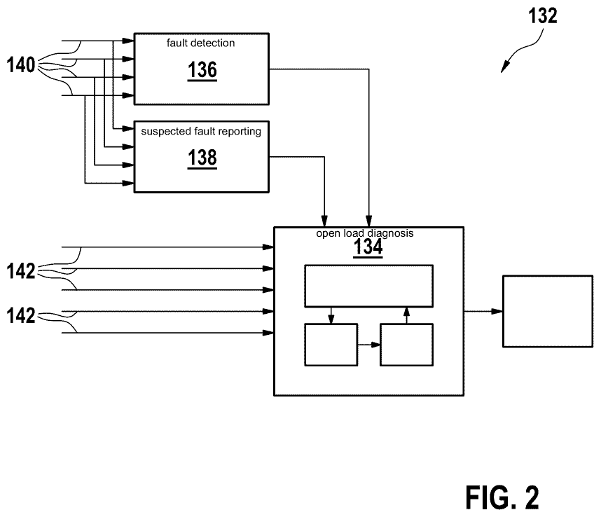

FIG. 2 is a software schematic diagram 132. The open load diagnosis 134 can include fault detection 136, suspected fault reporting 138, and signal detection 140. A report can be sent to a diagnostic manager 142. The open load diagnosis 134 can be performed using a physical temperature model 136 of an OK system. Furthermore, the open load diagnosis 134 can be carried out using a physical temperature model 138 of a WPA system. A parameter battery voltage, shutdown time, ambient temperature, and heater can each be included in the physical temperature model 136 and the physical temperature model 138, as shown schematically by arrows 140. Furthermore, the open load diagnosis 134 can be carried out based on sensor signals and an exhaust gas temperature model, which can take into account a wall temperature and/or a catalytic converter temperature, as shown schematically by arrows 142.

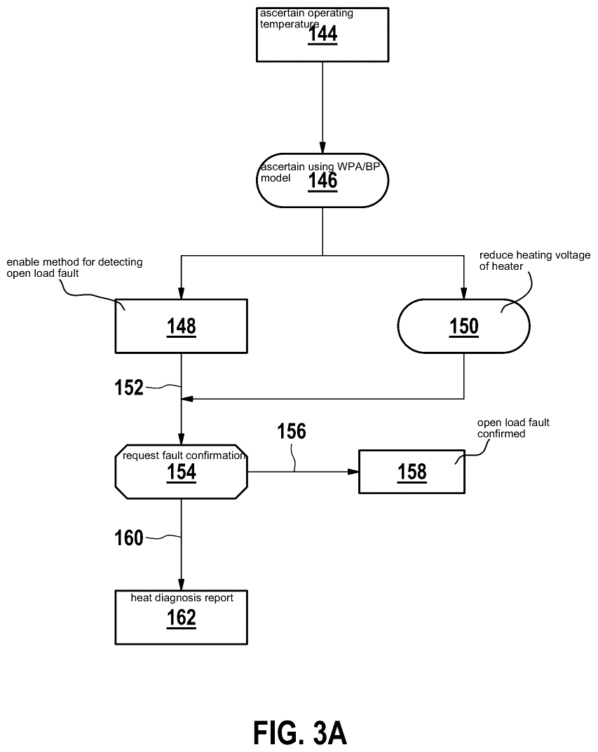

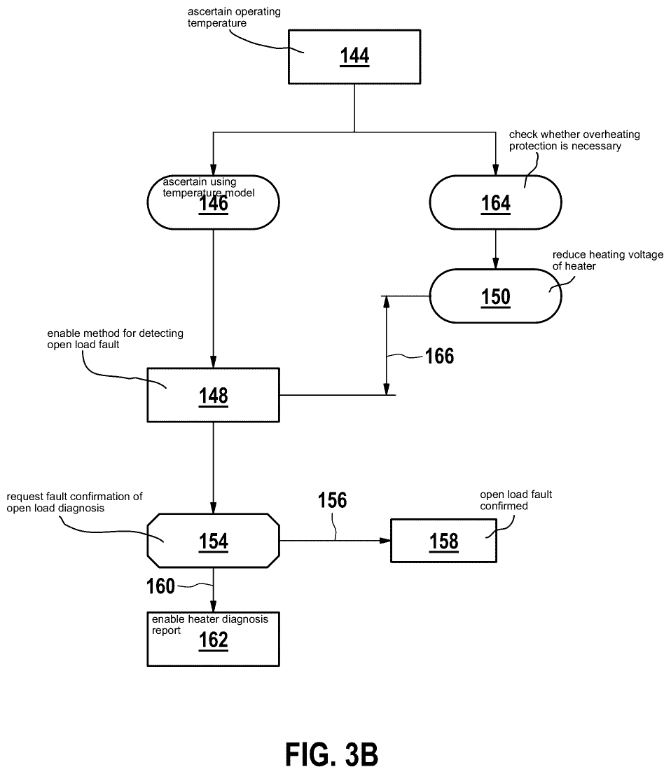

FIG. 3A shows a flow chart of the method according to the present invention. For heater control, as shown in field 144, an operating temperature of the wideband lambda sensor can be ascertained by means of at least one temperature model of the wideband lambda sensor, in particular by means of a WPA/BP model, as shown by field 146. If the operating temperature ascertained by the temperature model exceeds another defined limit value, the method for detecting the open load fault can be enabled, as shown by field 148. When enabling the method for detecting the open load fault to be carried out, a heating voltage of a heater of the wideband lambda sensor can be reduced at the same time, as shown by field 150, in particular in the case in which overheating protection is necessary. After a debounce time, as shown schematically by arrow 152, a fault confirmation of the open load diagnosis can be requested, as shown by field 154. If a fault is confirmed, as shown by arrow 156, an open load fault has occurred, as shown by field 158. If no fault is confirmed, as shown by arrow 160, a heater diagnosis report is enabled, as shown by field 162.

The permissible debounce time can thus be increased by simultaneously reducing the heater voltage and enabling the open load diagnosis. Depending on the selection of the reduced effective heater voltage, the debounce time can be extended.

FIG. 3B is a further flow chart of the method according to the present invention. The flow chart corresponds at least partially to the flow chart shown in FIG. 3A, so that reference can be made to the above description of FIG. 3A.

As shown in FIG. 3B, the operating temperature of the wideband lambda sensor can be ascertained by means of the temperature model, as shown schematically in field 146, wherein if the operating temperature ascertained by the temperature model exceeds a defined limit value, the method for detecting the open load fault can be enabled, as shown in field 148. The temperature model can be a WPA model.

By means of a further temperature model, in particular a BP model, as shown schematically in field 164, it can be checked whether overheating protection is necessary and the heater voltage can be reduced, as shown schematically in field 150. This allows an additional degree of freedom, as shown by arrow 166.

The requirements of a robust diagnosis and overheating protection can thus be divided between two heater models. By separately modeling the WPA model for enabling the open load diagnosis and a BP model for overheating protection, an additional degree of freedom can be provided which makes it possible to take into account a wider range of heater resistances. This becomes particularly relevant when a WPA heater is not yet warm enough to perform a robust diagnosis, while the BP heater is already threatening to overheat.

Both variants according to FIGS. 3A and 3B make it possible to increase the effective energy input for heating the sensor without the risk of damaging the sensor.

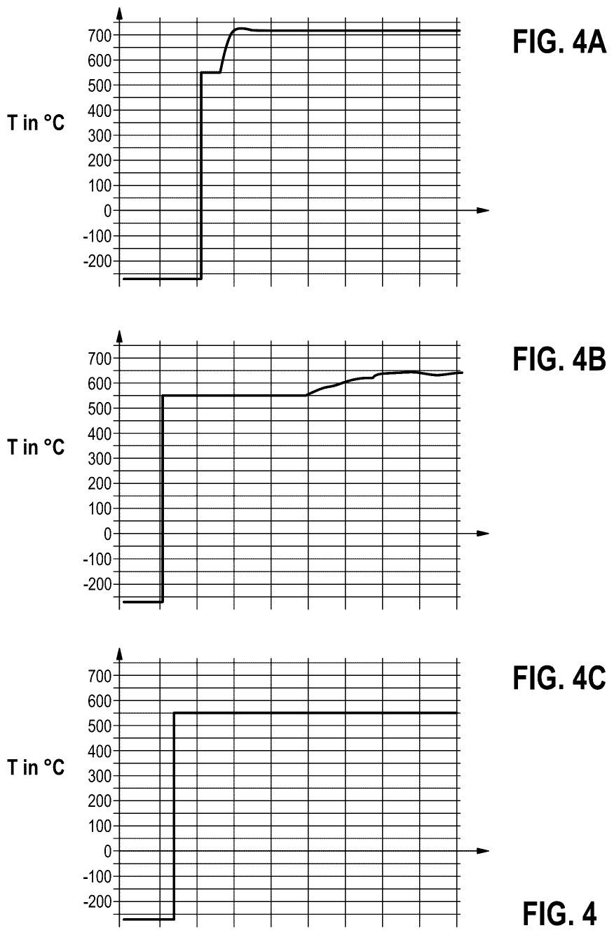

FIGS. 4A to 4C show temperature curves for a lambda sensor ceramic. FIG. 4A shows a temperature curve of a lambda sensor ceramic for an OK system, FIG. 4B shows a temperature curve of a lambda sensor ceramic for a system with a heater fault, and

FIG. 4C shows a temperature curve of a lambda sensor ceramic for a system with a cable break.

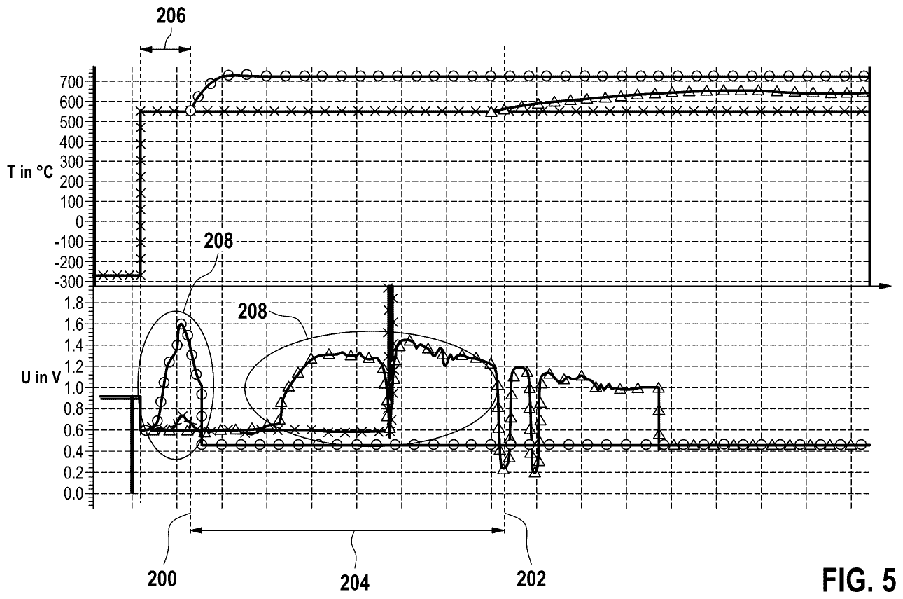

FIG. 5 shows temperature curves and sensor voltage signals for a lambda sensor ceramic. The temperature curves correspond to the temperature curves according to FIGS. 4A to 4C. The temperature curve of a lambda sensor ceramic for a OK system is shown by circles, the temperature curve of a lambda sensor ceramic for a system with a heater fault is shown by triangles, and the temperature curve of a lambda sensor ceramic for a system with a cable break is shown by crosses.

The sensor voltage signal of a lambda sensor ceramic for a OK system is shown by circles, the sensor voltage signal of a lambda sensor ceramic for a system with a heater fault is shown by triangles, and the sensor voltage signal of a lambda sensor ceramic for a system with a cable break is shown by crosses.

The point in time at which the open load diagnosis is enabled is shown by line 200, and a point in time for an end of the open load diagnosis is shown by line 202. This can result in a maximum waiting time in the case of a suspected fault, as shown by arrow 204. Furthermore, arrow 206 shows a minimum waiting time for the enabling of the open load diagnosis. Changes in the sensor voltage can be seen in the ranges 206.

1-10. (canceled)

11. A method for detecting an open load fault of a wideband lambda sensor, the wideband lambda sensor being configured to sense at least one property of an exhaust gas in an exhaust gas space of a motor vehicle, the wideband lambda sensor also including at least one heater, the method comprising the following steps:
a) enabling a fault check, wherein a temperature model is used to check when the wideband lambda sensor is sufficiently heated;
b) carrying out the fault check, wherein when no fault is detected according to the fault check, the following step is carried out:
b1) concluding the method with a result of OK, and wherein when a fault is detected according to the fault check, the following step is carried out:
b2) concluding the method with a result of not OK;
wherein before step b) is carried out, the necessity of overheating protection is checked, and based on the overheating protection being necessary, a heater voltage of the heater is reduced simultaneously with step a) or before step a) is carried out.

12. The method according to claim 11, wherein the temperature model is selected from the group including: a WPA model, a BP model, a WPA/BP model.

13. The method according to claim 11, wherein the temperature model is a WPA/BP model, wherein the necessity of overheating protection is checked using the WPA/BP model.

14. The method according to claim 11, wherein in step a), it is checked whether an operating temperature of the wideband lambda sensor ascertained by the temperature model exceeds a defined limit value.

15. The method according to claim 11, wherein the temperature model is a WPA model, wherein the checking of the necessity of the overheating protection is carried out using a further temperature model.

16. The method according to claim 11, wherein the further temperature model is a BP model.

17. The method according to claim 11, wherein in the fault check in step b), a comparison of a measured internal resistance with a diagnostic threshold takes place.

18. A system, comprising:
at least one wideband lambda sensor; and
at least one controller including at least one processor, wherein the controller is configured to detecting an open load fault of the wideband lambda sensor, the wideband lambda sensor being configured to sense at least one property of an exhaust gas in an exhaust gas space of a motor vehicle, the wideband lambda sensor also including at least one heater, the controller being configured to:
a) enable a fault check, wherein a temperature model is used to check when the wideband lambda sensor is sufficiently heated;
b) carry out the fault check, wherein when no fault is detected according to the fault check, the following step is carried out:
b1) conclude the method with a result of OK, and wherein when a fault is detected according to the fault check, the following step is carried out:
b2) conclude the method with a result of not OK;
wherein before b) is carried out, the necessity of overheating protection is checked, and based on the overheating protection being necessary, a heater voltage of the heater is reduced simultaneously with a) or before a) is carried out.

19. A non-transitory data carrier on which is stored a computer program which is configured to for detecting an open load fault of a wideband lambda sensor, the wideband lambda sensor being configured to sense at least one property of an exhaust gas in an exhaust gas space of a motor vehicle, the wideband lambda sensor also including at least one heater, the computer program, when executed by a computer or computer network, causing the computer or computer network to perform the following steps:
a) enabling a fault check, wherein a temperature model is used to check when the wideband lambda sensor is sufficiently heated;
b) carrying out the fault check, wherein when no fault is detected according to the fault check, the following step is carried out:
b1) concluding the method with a result of OK, and wherein when a fault is detected according to the fault check, the following step is carried out:
b2) concluding the method with a result of not OK;
wherein before step b) is carried out, the necessity of overheating protection is checked, and based on the overheating protection being necessary, a heater voltage of the heater is reduced simultaneously with step a) or before step a) is carried out.

20. A non-transitory data carrier on which a data structure is stored which is configured for detecting an open load fault of a wideband lambda sensor, the wideband lambda sensor being configured to sense at least one property of an exhaust gas in an exhaust gas space of a motor vehicle, the wideband lambda sensor also including at least one heater, the data structure, after being loaded into a working and/or main memory of a computer or computer network, causing the computer or computer network to perform the following steps:
a) enabling a fault check, wherein a temperature model is used to check when the wideband lambda sensor is sufficiently heated;
b) carrying out the fault check, wherein when no fault is detected according to the fault check, the following step is carried out:
b1) concluding the method with a result of OK, and wherein when a fault is detected according to the fault check, the following step is carried out:
b2) concluding the method with a result of not OK;
wherein before step b) is carried out, the necessity of overheating protection is checked, and based on the overheating protection being necessary, a heater voltage of the heater is reduced simultaneously with step a) or before step a) is carried out.
